(19) United States
(12) Patent Application Publication
(10) Pub. No.: US 2010/0252888 A1
(43) Pub. Date: Oct. 7, 2010

(54) SEMICONDUCTOR DEVICE

(75) Inventor: Toshiyuki IWAMOTO, Kanagawa (JP)

Correspondence Address: YOUNG & THOMPSON, 209 Madison Street, Suite 500, Alexandria, VA, 22314, US

(73) Assignee: NEC Electronics Corporation, Kanagawa (JP)

(21) Appl. No.: 12/727,430

(22) Filed: Mar. 19, 2010

(30) Foreign Application Priority Data
Mar. 27, 2009 (JP) 2009-78384

(51) Int. Cl. H01L 27/092

(52) U.S. Cl. 257/369; 257/E27.062

(57) ABSTRACT

A semiconductor device includes a field-effect transistor on a substrate. The field-effect transistor includes a gate insulating film and a gate electrode. The gate electrode has a laminated structure including a first electrode layer made of a first metal, a second electrode layer made of a second metal, and a third electrode layer made of a silicon layer. The second metal is a material having a workfunction for alleviating band discontinuity between the first electrode layer and the third electrode layer, with respect to a majority carrier of the silicon layer.

This application is based on Japanese Patent Application No. 2009-078384.

### BACKGROUND OF THE INVENTION

The present invention relates to a semiconductor device and a method for manufacturing the semiconductor device.

In recent years, a deterioration in a drive current due to a depletion of carriers in a polysilicon gate electrode constituting each MOSFET (Metal-Oxide Semiconductor Field Effect Transistor) and a gate leakage current due to a decrease in the thickness of a gate insulating film have become problematic as LSIs have been increasingly miniaturized. Hence, a study is being made of a technique to avoid a depletion of carriers in an electrode by using a metal gate electrode described in Japanese Patent Laid-Open No. 2005-294422 and a technique to reduce a gate leakage current by using a high-dielectric film (high-k film) for a gate insulating film and thereby increasing the physical thickness thereof.

For example, as one of structures using a metal gate electrode, National Publication of International Patent Application No. 2008-537359, Japanese Patent Laid-Open No. 2007-208260, and Japanese Patent Laid-Open No. 2007-158065 disclose MIPS (Metal Inserted Poly-Silicon) structures in which a metal gate electrode is interposed between a High-k film and a polysilicon gate electrode.

However, the inventor of the present application has newly found that the MIPS structures disclosed in these related art documents have the following problem: contact resistance between the metal gate electrode and the polysilicon gate electrode is high in a field-effect transistor having such a conventional MIPS structure. Consequently, there arises a problem of degradation in AC characteristics (temporal characteristics of varying (alternating-current) input-output signals in a digital IC).

As a method for reducing contact resistance, a structure is available in which a polysilicon gate electrode on a metal gate electrode is composed of metal, as described in Japanese Patent Laid-Open No. 2005-294422. However, the film thickness of the metal gate electrode is larger in such a structure than in the MIPS structure, thus causing the problem that gate processing is difficult to perform.

Accordingly, the above-described related arts have difficulties in simultaneously achieving both the improvement of AC operation and the simplification of gate processing.

### SUMMARY

According to the present invention, there is provided a semiconductor device including:

a semiconductor substrate;

an NMOS including a first gate insulating film on the substrate and a first gate electrode including a layer of a first metal on the first gate insulating film, a layer of a second metal on the layer of the first metal, and a layer of n-type doped polysilicon on the layer of the second metal; and

a PMOS including a second gate insulating film on the substrate and a second gate electrode including a layer of a third metal on the second gate insulating film, a layer of a fourth metal on the layer of the third metal, and a layer of p-type doped polysilicon on the layer of the fourth metal,

wherein EF1 which is a workfunction of the first metal, EF2 which is a workfunction of the second metal, EF3 which is a workfunction of the third metal, EF4 which is a workfunction of the fourth metal, EfN which is a Fermi level of the n-type doped polysilicon, and EfP which is a Fermi level of the p-type doped polysilicon satisfy the following expressions (1) and (2):

|EF1−EfN|>EF2−EfN; and (1)

|EF3−EfP|>EfP−EF4. (2)

According to this aspect of the present invention, the semiconductor device includes the second metal layer satisfying the above-described expression (1) between the layer of the first metal and the n-type doped polysilicon layer, and the fourth electrode layer made of the second metal satisfying the above-described expression (2) between the third metal layer and the p-type doped polysilicon layer. Consequently, it is possible to alleviate band discontinuity between the second metal layer and the n-type doped polysilicon layer or between the fourth metal layer and the p-type doped polysilicon layer, with respect to a majority carrier of silicon. Thus, a reduction can be made in contact resistance between a metal gate electrode and a silicon gate electrode. In addition, the second metal layer and the fourth metal layer can be easily film-formed on the layer of the first metal and on the third metal layer using a sputtering method or the like. It is therefore possible to easily obtain an MIPS structure the AC operation of which has been improved.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view illustrating a semiconductor device of a first embodiment;

FIGS. 2A to 2D are cross-sectional views illustrating steps for manufacturing the semiconductor device of the first embodiment;

FIGS. 3A to 3D are cross-sectional views illustrating steps for manufacturing the semiconductor device of the first embodiment;

FIGS. 4A to 4D are cross-sectional views illustrating steps for manufacturing the semiconductor device of the first embodiment;

FIGS. 5A to 5D are cross-sectional views illustrating steps for manufacturing the semiconductor device of the first embodiment;

FIGS. 6A to 6D are cross-sectional views illustrating steps for manufacturing the semiconductor device of the first embodiment;

FIGS. 7A to 7D are cross-sectional views illustrating steps for manufacturing the semiconductor device of the first embodiment;

FIGS. 8A to 8D are cross-sectional views illustrating steps for manufacturing the semiconductor device of the first embodiment;

FIGS. 9A to 9D are cross-sectional views illustrating steps for manufacturing the semiconductor device of the first embodiment;

FIGS. 10A to 10D are cross-sectional views illustrating steps for manufacturing the semiconductor device of the first embodiment;

FIGS. 11A to 11D are cross-sectional views illustrating steps for manufacturing the semiconductor device of the first embodiment;

FIG. 12 is a cross-sectional view illustrating a semiconductor device of a second embodiment;

FIGS. 13A and 13B are cross-sectional views illustrating steps for manufacturing the semiconductor device of the second embodiment;

FIG. 14 is a cross-sectional view illustrating a semiconductor device of a third embodiment;

FIGS. 15A and 15B are cross-sectional views illustrating steps for manufacturing the semiconductor device of the third embodiment;

FIGS. 16A and 16B are schematic views used to explain operational effects of the semiconductor devices of the first to third embodiments; and

FIG. 17 is a graphical view illustrating workfunctions of metals in comparison with band edges of silicon.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, embodiments of the present invention will be described using the accompanying drawings. Note that throughout the drawings, the same components are denoted by the same reference numerals and will be omitted from the description as appropriate.

### First Embodiment

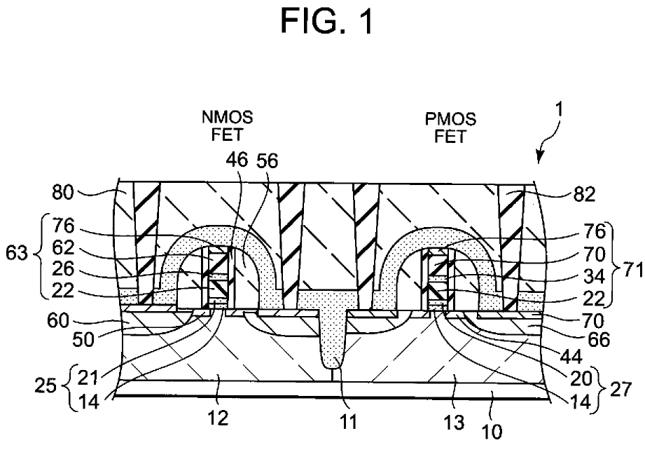

FIG. 1 is a cross-sectional view illustrating a semiconductor device 1 in accordance with a first embodiment of the present invention. The semiconductor device 1 includes an NMOSFET (n-channel field-effect transistor) and a PMOSFET (p-channel field-effect transistor) on a semiconductor substrate 10. The NMOSFET includes a gate insulating film 25 formed on the semiconductor substrate 10 and a gate electrode 63 formed on the gate insulating film 25. The gate electrode 63 is composed of a laminated structure including a metal electrode layer 22 (first electrode layer) made of a metal M1 (first metal) and formed on the gate insulating film 25, a metal electrode layer 26 (second electrode layer) made of a metal M2N (second metal) and formed on the metal electrode layer 22, and an n-type polysilicon electrode layer 62 (third electrode layer) made of n-type polysilicon and formed on the metal electrode layer 26. In addition, the PMOSFET includes a gate insulating film 27 formed on the semiconductor substrate 10 and a gate electrode 71 formed on the gate insulating film 27. The gate electrode 71 is composed of a laminated structure including a metal electrode layer 22 (first electrode layer) made of the metal M1 and formed on the gate insulating film 27, a metal electrode layer 34 (second electrode layer) made of a metal M2P (second metal) and formed on the metal electrode layer 22, and a p-type polysilicon electrode layer 70 (third electrode layer) made of p-type polysilicon and formed on the metal electrode layer 34. Assuming that the workfunction of the metal M1 is EF1, the workfunction of the metal M2N is EF2N, the workfunction of the metal M2P is EF2P, the Fermi level of the n-type polysilicon is EfN, and the Fermi level of the p-type polysilicon is EfP, then the following expressions (1) and (2) are satisfied.

|EF1−EfN|>EF2N−EfN (1)

|EF1−EfP|>EfP−EF2P (2)

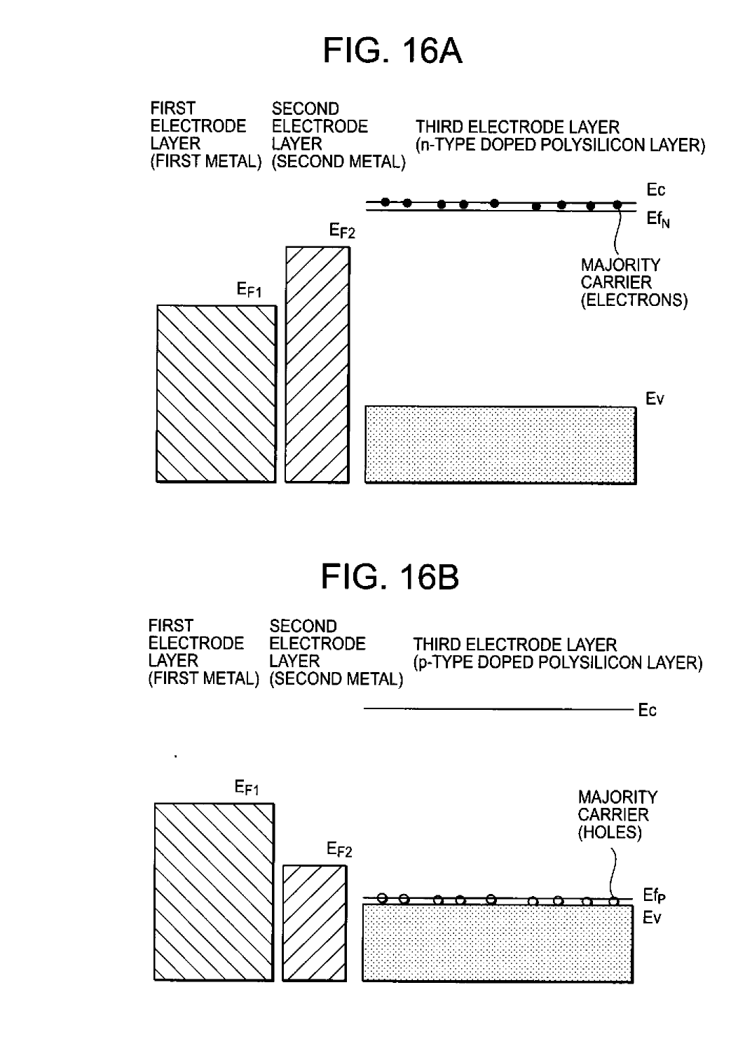

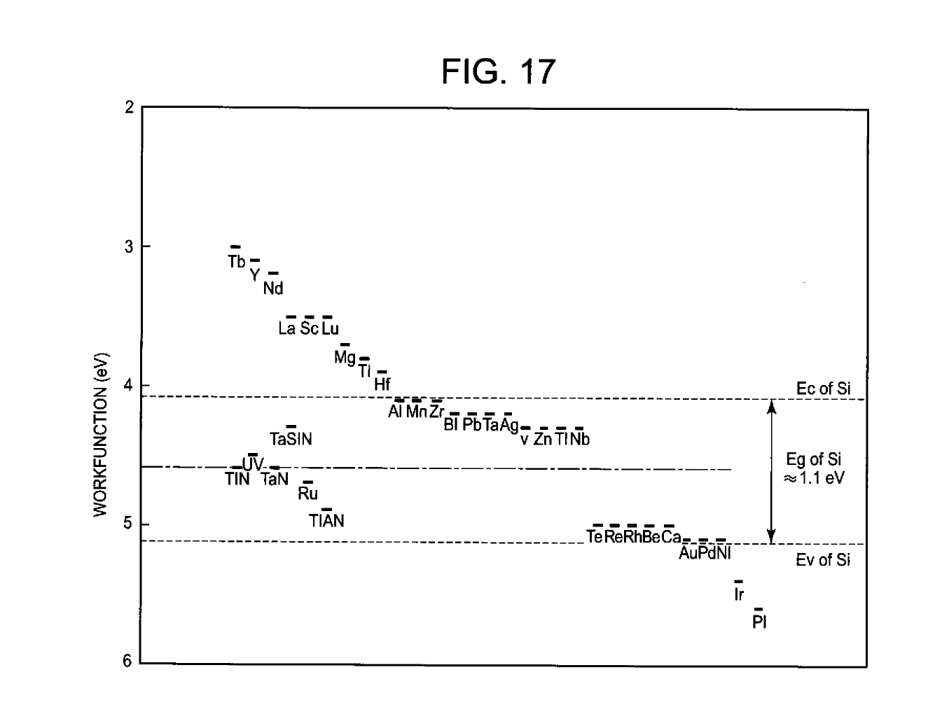

First, the meanings of the above-described expressions (1) and (2) will be explained using FIGS. 16 and 17. FIG. 16A is a schematic view used to explain a relationship between the members of the above-described expression (1). FIG. 16B is a schematic view used to explain a relationship between the members of the above-described expression (2). FIG. 17 is a graphical view illustrating workfunctions of metals in comparison with band edges of silicon. The workfunction of each metal can be measured using a photoemission method and a transistor. As illustrated in FIG. 16, the metal electrode layers 26 and 34 respectively alleviate band discontinuity between the metal electrode layer 22 and the silicon electrode layer 62 and between the metal electrode layer 22 and the silicon electrode layer 70, with respect to the majority carriers of the silicon electrode layers 62 and 70.

In the case of the n-type polysilicon electrode layer 62, a metal having a workfunction closer to a Fermi level of silicon than that of the metal M1 or a metal having a workfunction at a level lower than a conduction band Ec of silicon is used as the metal M2N, in order to reduce contact resistance. By injecting a majority carrier (electrons) into silicon, a difference between an effective conduction band of silicon (i.e., the Fermi level EfN of n-type polysilicon) and the workfunction of the metal M2N is made smaller, compared with a difference between the Fermi level EfN of silicon and the workfunction of the metal M2N. Hence, as the metal M2N, a selection is made of a metal smaller in workfunction difference from the Fermi level EfN of n-type polysilicon than the metal M1 or a metal the energy level of which is lower than the Fermi level EfN of n-type polysilicon.

In the case of the p-type polysilicon electrode layer 70, a metal having a workfunction closer to the Fermi level of silicon than that of the metal M1 or a metal having a workfunction at a level higher than a valence band Ev of silicon is sued as the metal M2P, in order to reduce contact resistance. By injecting a majority carrier (holes) into silicon, a difference between an effective Fermi level of silicon (i.e., the Fermi level EfP of p-type polysilicon) and the workfunction of the metal M2P is made smaller, compared with a difference between the Fermi level EfP of silicon and the workfunction of the metal M2P. Hence, as the metal M2P, a selection is made of a metal smaller in workfunction difference from the Fermi level EfP of p-type polysilicon than the metal M1 or a metal the energy level of which is higher than the Fermi level EfP of p-type polysilicon.

Specifically, a metal having such a workfunction that the Fermi level of the metal is positioned near a mid-gap of silicon is used as the metal M1. Preferably, the metal M1 has a workfunction of 4.2 to 4.9 eV. Specifically, the metal M1 may be at least one metal selected from the group consisting of TiN, W, TaN, TaSiN, Ru and TiAlN. Particularly preferably, TiN, TaN or TaSiN is used.

In addition, the metal M2N preferably has a workfunction of 3.0 to 4.3 eV. Specifically, the metal M2N may be at least one metal selected from the group consisting of Tb, Y, Nd, La, Sc, Lu, Mg, Tl, Hf, Al, Mn, Zr, Bi, Pb, Ta, Ag, V, Zn, Ti and Nb. More preferably, the metal M2N is at least one metal selected from the group consisting of Tb, Y, Nd, La, Sc, Lu, Mg, Tl, Hf, Al, Mn and Zr. Particularly preferably, Al, Zr, Mn, Hf or Tl is used.

In addition, the metal M2P preferably has a workfunction of 5.0 to 6.0 eV. Specifically, the metal M2P may be at least one metal selected from the group consisting of Te, Re, Rh, Be, Co, Au, Pb, Ni, Ir and Pt. Particularly preferably, Ir, Pt or Ni is used.

The gate insulating films 25 and 27 are preferably high-dielectric insulating films. Preferably, HfO₂, ZrO₂, HfSiON, La₂O₃, HfAlO or the like is used. Particularly preferably, HfO₂ is used. The thickness of these films is preferably 1.0 nm or larger but not larger than 5.0 nm. FIG. 1 illustrates an example in which the gate insulating film 25 includes an oxynitride film 14 and a high-dielectric, La (lanthanum)-containing gate insulating film 21 and the gate insulating film 27 includes an oxynitride film 14 and a high-dielectric gate insulating film 20. The oxynitride film 14 functions as an interface insulator.

The film thickness of the metal electrode layer 22 is preferably within a range from 1.0 nm to 20.0 nm. The film thickness of the metal electrode layer 26 is preferably within a range from 0.1 nm to 5.0 nm. The film thickness of the metal electrode layer 34 is preferably within a range from 0.1 nm to 5.0 nm.

Either amorphous silicon or polysilicon may be used for the n-type polysilicon electrode layer 62 and the p-type polysilicon electrode layer 70, respectively.

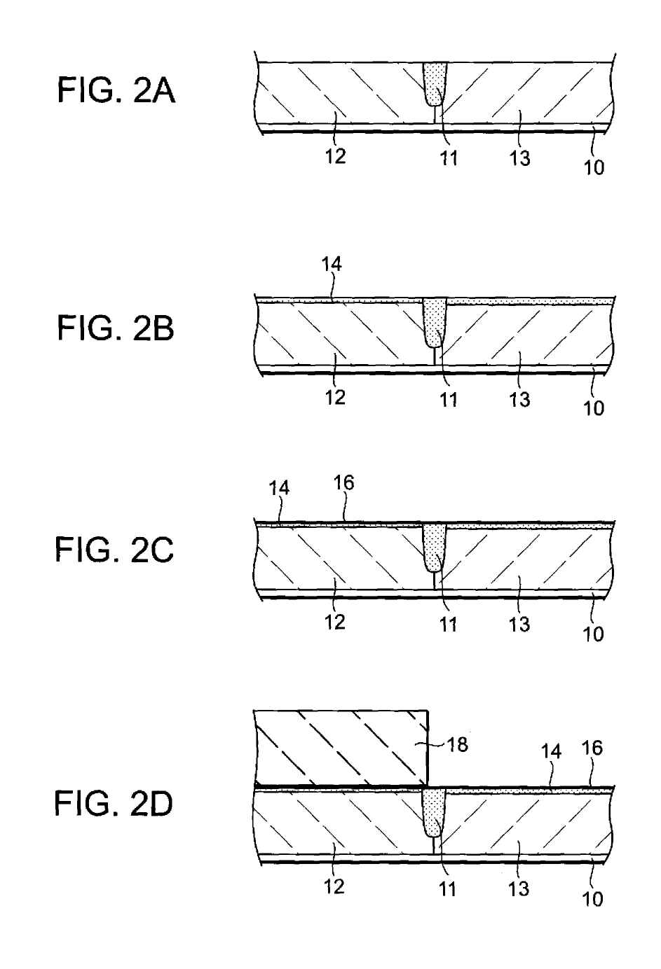

Next, a method for manufacturing a semiconductor device in accordance with an embodiment of the present invention will be described with reference to the cross-sectional views of FIG. 2 to FIG. 11.

First, as illustrated in FIG. 2A, an element-isolating oxide film 11 is formed on a semiconductor substrate 10. The element-isolating oxide film 11 is formed by means of conventionally used STI (Shallow Trench Isolation). After that, a P well 12 is formed in an NMOSFET-forming region and an N well 13 is formed in a PMOSFET-forming region.

Then, as illustrated in FIG. 2B, a 1.0 nm-thick oxynitride film 14 is formed as an interface insulating film. Specifically, a silicon oxide film is formed by means of thermal oxidation using a sulfuric acid/hydrogen peroxide mixture solution, ozone water, hydrochloric acid/ozone water, or the like. Then, a plasma nitriding treatment is performed on the silicon oxide film thus obtained, thereby forming the oxynitride film 14.

After that, as illustrated in FIG. 2C, an La film 16 is formed using a sputtering method. The film thickness of the La film 16 is within a range from 0.1 nm to 2.0 nm. La is a metal used to control the threshold voltage of the NMOSFET. As an alternative to La, Dy (dysprosium) may be used.

Then, as illustrated in FIG. 2D, a resist mask 18 is formed.

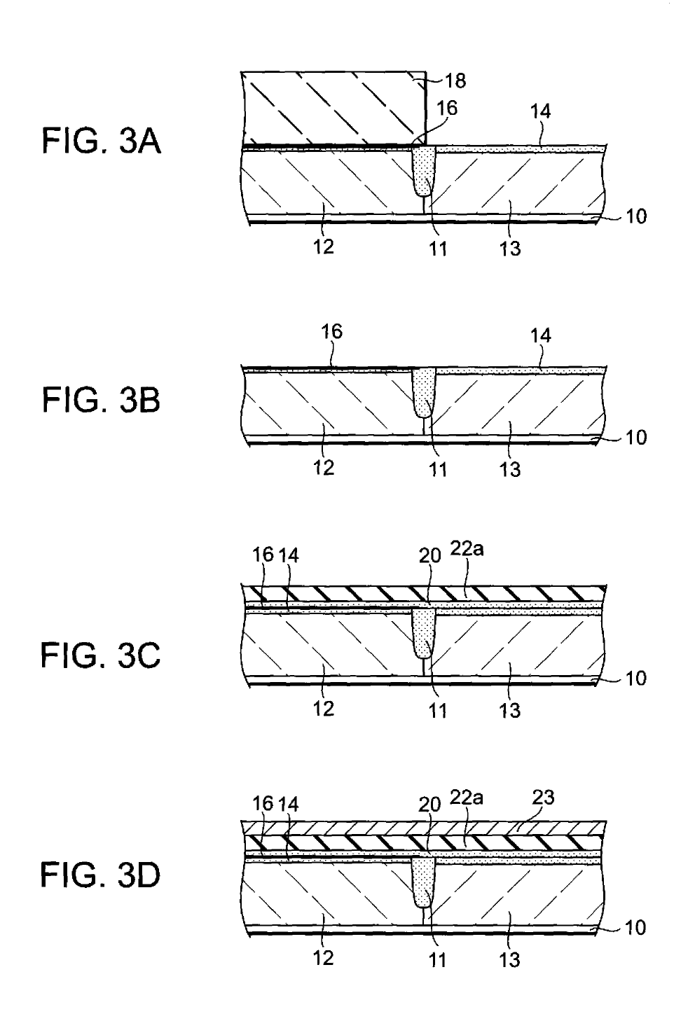

Next, as illustrated in FIG. 3A, the La film 16 in the PMOSFET-forming region is removed by means of wet treatment. For the wet treatment of the La film 16, diluted hydrochloric acid is used.

Then, after the removal of the La film 16 in the PMOSFET-forming region, the resist mask 18 is removed by means of ashing treatment (FIG. 3B).

Subsequently, as illustrated in FIG. 3C, a high-dielectric gate insulating film 20 is formed. A method for forming the gate insulating film 20 is selected from a CVD method (chemical vapor deposition method), an ALCVD method (atomic layer chemical vapor deposition method) and a sputtering method. Next, a first metal layer 22a is formed. Next, as illustrated in as illustrated in FIG. 3D, a hard mask 23 is formed. The hard mask 23 is made of at least one material selected from the group consisting of a silicon oxide film, a silicon nitride film, and an amorphous carbon film.

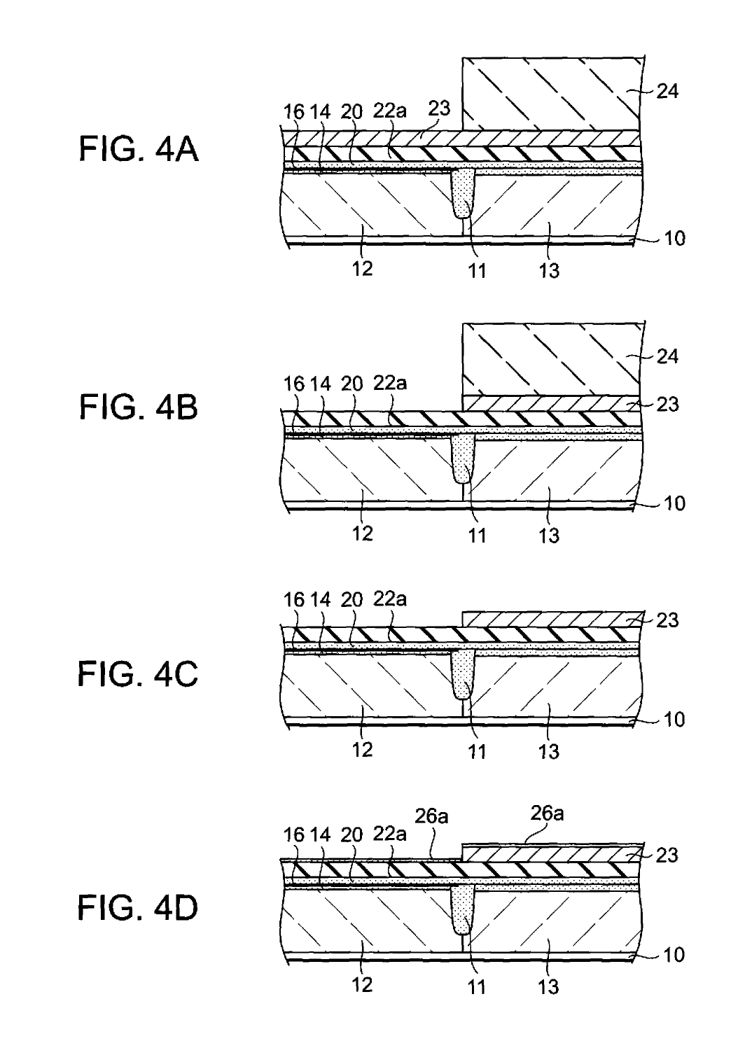

Then, as illustrated in FIG. 4A, an opening is created in the NMOSFET-forming region using a resist mask 24. In addition, as illustrated in FIG. 4B, the hard mask 23 in the NMOSFET-forming region is removed. After that, the resist mask 24 is removed (FIG. 4C).

Subsequently, as illustrated in FIG. 4D, a second metal layer 26a is formed on the exposed surfaces of the layer of the first metal 22a and the hard mask 23 using a sputtering method.

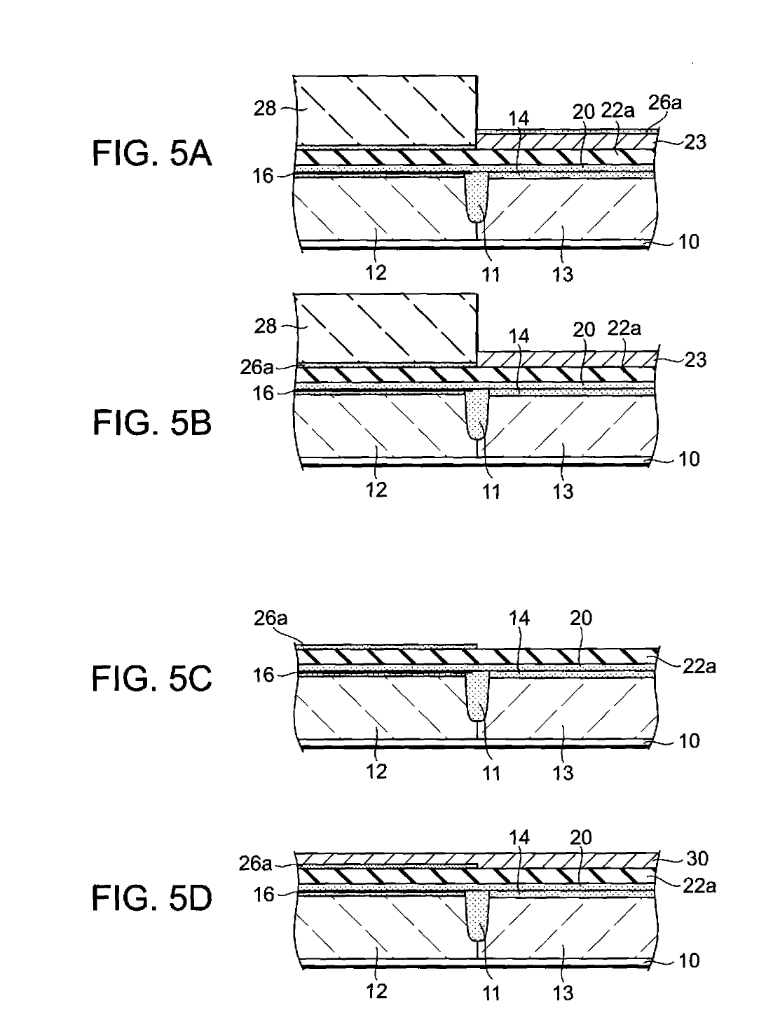

Next, as illustrated in FIG. 5A, a resist mask 28 is formed to create an opening in the PMOSFET-forming region. Subsequently, the second metal layer 26a in the PMOSFET-forming region is removed by means of dry etching (FIG. 5B). Then, the resist mask 28 and the hard mask 23 are removed (FIG. 5C). The resist mask 28 can be removed by means of wet treatment.

Next, as illustrated in FIG. 5D, a hard mask 30 is formed. The hard mask 30 is made of at least one material selected from the group consisting of a silicon oxide film, a silicon nitride film and an amorphous carbon film.

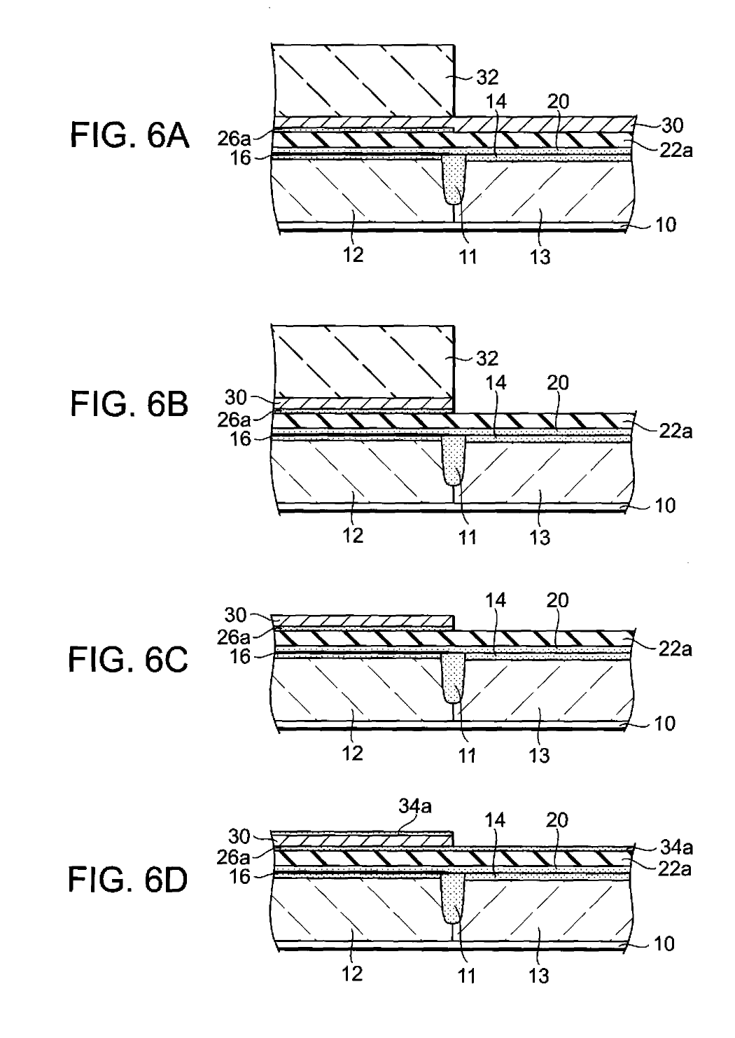

Then, as illustrated in FIG. 6A, an opening is created in the PMOSFET-forming region using a resist mask 32. In addition, as illustrated in FIG. 6B, the hard mask 30 in the PMOSFET-forming region is removed. After that, the resist mask 32 is removed (FIG. 6C).

Subsequently, as illustrated in FIG. 6D, a second metal layer 34a is formed on the exposed surfaces of the layer of the first metal 22a and the hard mask 30 using a sputtering method.

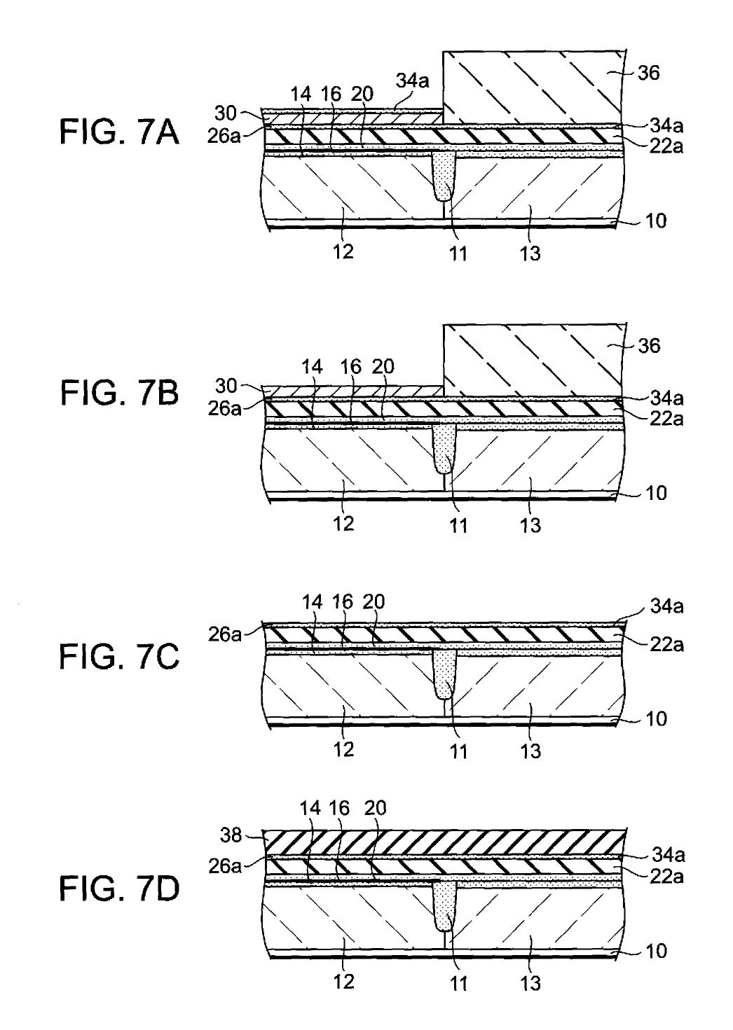

Next, as illustrated in FIG. 7A, a resist mask 36 is formed to create an opening in the NMOSFET-forming region. Subsequently, the second metal layer 34a in the NMOSFET-forming region is removed by means of dry etching (FIG. 7B). Here, the resist mask 36 can also be removed by means of wet treatment. Then, the resist mask 36 and the hard mask 30 are removed (FIG. 7C). In this way, the second metal layer 34a is formed in the PMOSFET-forming region.

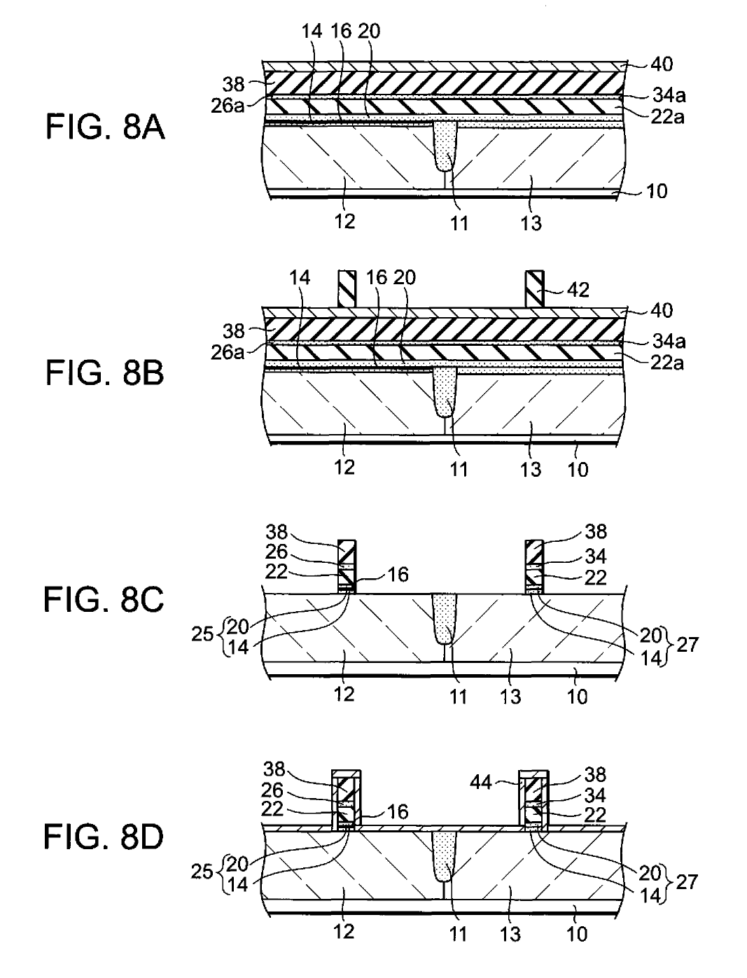

Then, as illustrated in FIG. 7D, a silicon layer 38 is formed. Subsequently, a hard mask 40 is formed (FIG. 8A).

Next, as illustrated in FIG. 8B, a resist mask 42 is formed. After that, as illustrated in FIG. 8C, the layer of the first metal 22a, the second metal layer 26a and the silicon layer 38 in the NMOSFET-forming region are processed into a gate electrode shape by means of dry etching and wet treatment, thereby forming a gate electrode composed of a laminated structure including the metal electrode layer 22, the metal electrode layer 26 and the silicon layer 38. Concurrently, the layer of the first metal 22a, the second metal layer 34a and the silicon layer 38 in the PMOSFET-forming region are processed into a gate electrode shape, thereby forming a gate electrode composed of a laminated structure including the metal electrode layer 22, the metal electrode layer 34 and the silicon layer 38. At this time, as illustrated in the figures, the oxynitride film 14, the La film 16 and the gate insulating film 20 are also etched.

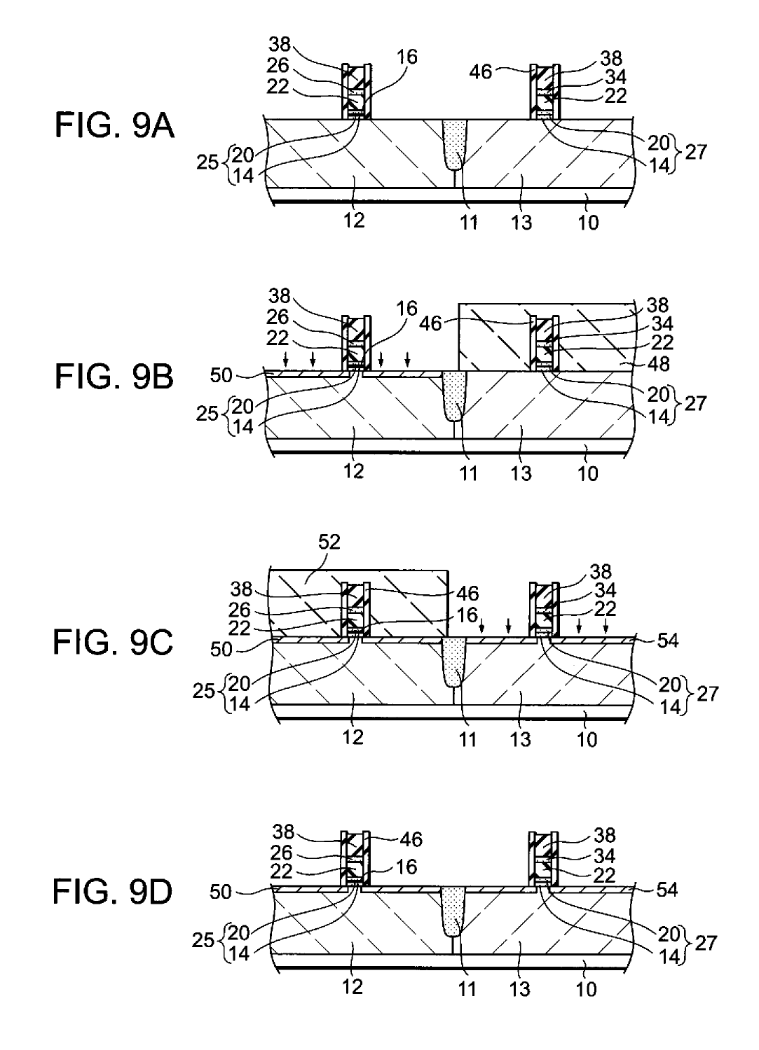

After that, a silicon nitride film 44 is formed using an ALCVD method (FIG. 8D), and an offset spacer 46 is formed (FIG. 9A). For the offset spacer 46, a silicon oxide film or a laminated structure composed of a silicon nitride film and a silicon oxide film may be used.

After that, as illustrated in FIG. 9B, an extension region 50 is formed in the NMOSFET-forming region by means of ion implantation using a resist mask 48. Implantation conditions are as follows:

As: implantation energy=2 keV, dose amount=8E14 atoms/cm², implantation angle=0°; and

BF₂: implantation energy=50 keV, dose amount=3E13 atoms/cm², implantation angle=30°.

Subsequently, an extension region 54 is likewise formed in the PMOSFET-forming region by means of ion implantation using a resist mask 52 (FIG. 9C). Implantation conditions are as follows:

BF₂: implantation energy=3 keV, dose amount=8E14 atoms/cm², implantation angle=0°; and

As: implantation energy=50 keV, dose amount=3E13 atoms/cm², implantation angle=30°.

After ion implantation, the resist mask 52 is removed (FIG. 9D).

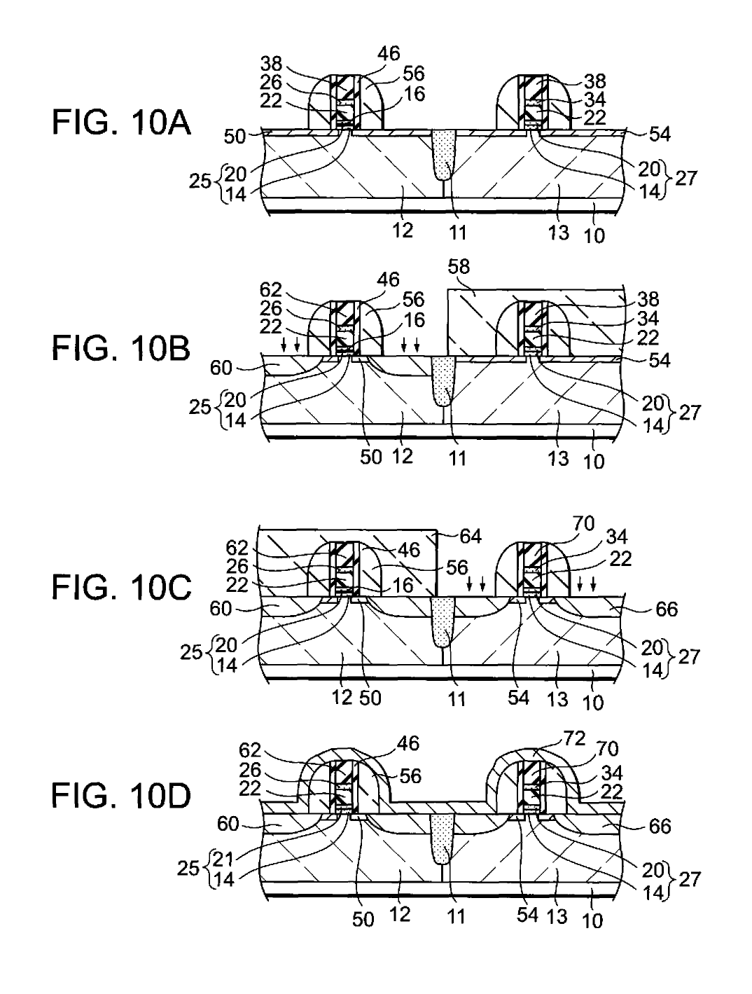

Then, a sidewall spacer film composed of a nitride film or an oxide film is formed, and then a sidewall spacer film 56 is formed by means of dry etching, as illustrated in FIG. 10A.

After that, as illustrated in FIG. 10B, a deep SD region 60 is formed in the NMOSFET-forming region by means of ion implantation using a resist mask 58. Implantation conditions are as follows:

Ge: implantation energy=30 keV, dose amount=5E14 atoms/cm², implantation angle=0°;

As: implantation energy=20 keV, dose amount=3E15 atoms/cm², implantation angle=0°; and

P: implantation energy=20 keV, dose amount=5E13 atoms/cm², implantation angle=0°.

At this time, ions are also implanted into a silicon layer of the gate electrode to form an n-type polysilicon electrode layer 62 made of n-type polysilicon. After that, the resist mask 58 is removed. The implantation energy of As is preferably 5 keV or higher but not higher than 30 keV, and more preferably 10 keV or higher but not higher than 20 keV. The dose amount of As is preferably 1E15 atoms/cm² or larger but not larger than 5E15 atoms/cm², and more preferably 2E15 atoms/cm² or larger but not larger than 3E15 atoms/cm².

Subsequently, as illustrated in FIG. 10C, a deep SD region 66 is likewise formed in the PMOSFET-forming region by means of ion implantation using a resist mask 64. Implantation conditions are as follows:

Ge: implantation energy=30 keV, dose amount=5E14 atoms/cm², implantation angle=0°;

B: implantation energy=7 keV, dose amount=5.0E13 atoms/cm², implantation angle=0°;

BF₂: implantation energy=15 keV, dose amount 5E14=atoms/cm², implantation angle=0°; and

BF₂: implantation energy=9 keV, dose amount=2E15 atoms/cm², implantation angle=0°.

At this time, ions are also implanted into a silicon layer of the gate electrode to form a p-type polysilicon electrode layer 70 made of p-type polysilicon. After that, the resist mask 64 is removed. A forth implantation energy of BF₂ is preferably 5 keV or higher but not higher than 15 keV, and more preferably 8 keV or higher but not higher than 12 keV. A fourth dose amount of BF₂ is preferably 1E15 atoms/cm² or larger but not larger than 5E15 atoms/cm², and more preferably 2E15 atoms/cm² or larger but not larger than 3E15 atoms/cm².

Next, a heat treatment is performed to activate the dopants of the extension regions 50 and 54 and the deep SD regions 60 and 66. Heat treatment conditions are set as 1050° C., 0 seconds. At this time, La in the La film 16 diffuses into the high-dielectric gate insulating film 20 of the NMOSFET-forming region. Consequently, a gate insulating film 21 containing high-dielectric La is formed in the NMOSFET.

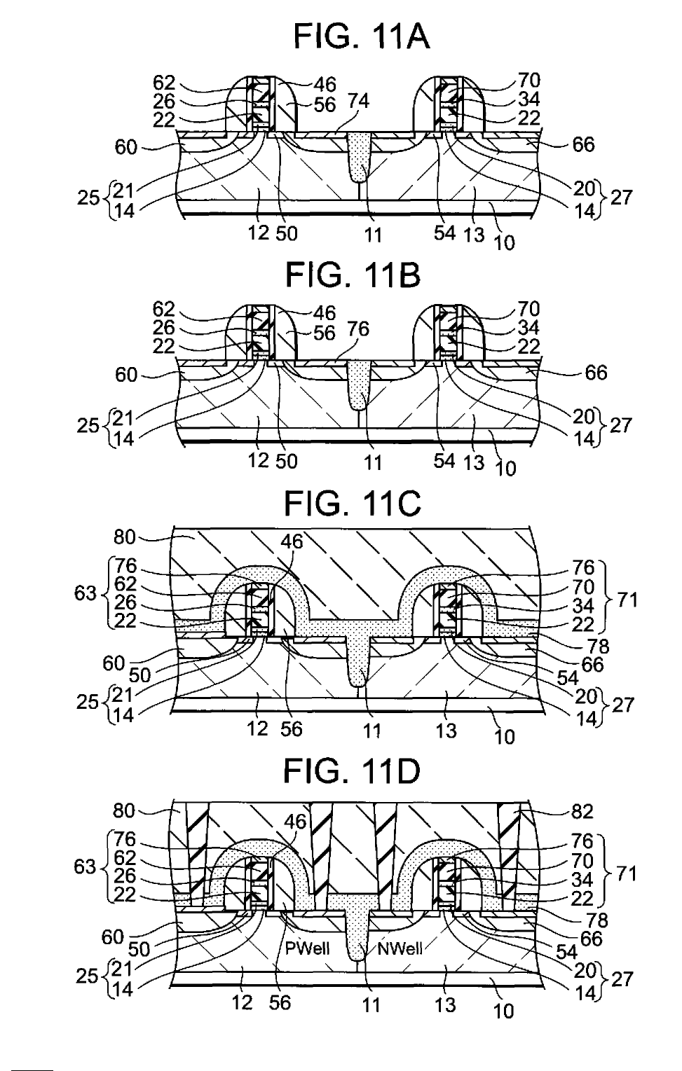

After that, as illustrated in FIG. 10D, an NiPt film 72 is formed using a sputtering method. Then, an excess NiPt film 72 is removed by means of heat treatment and using aqua regia, thereby forming a primary silicide layer 74 (FIG. 11A). A heat treatment is further performed to form a secondary silicide layer 76 (FIG. 11B).

Then, as illustrated in FIG. 11C, a contact etching stopper film 78 is formed. The type of this film is a nitride film and the thickness thereof is 10 nm or larger but not larger than 100 nm. Furthermore, an interlayer film 80 composed of an oxide film is formed. Still furthermore, as illustrated in FIG. 11D, a contact 82 is formed. Consequently, the semiconductor device 1 of FIG. 1 is obtained.

Next, operational effects of the present embodiment will be described. According to the semiconductor device 1, the metal electrode layer 26 made of the metal M2N satisfying the above-described expression (1) is included between the metal electrode layer 22 made of the metal M1 and the silicon electrode layer 62 made of silicon. In addition, the metal electrode layer 34 made of the metal M2P satisfying the above-described expression (2) is included between the metal electrode layer 22 made of the metal M1 and the silicon electrode layer 70 made of silicon. This structure can alleviate band discontinuity between the metal electrode layer 22 and the silicon electrode layer 62 and between the metal electrode layer 22 and the silicon electrode layer 70, with respect to majority carriers of silicon. Thus, it is possible to reduce contact resistance between the metal electrode layer 22 and the silicon electrode layer 62 and between the metal electrode layer 22 and the silicon electrode layer 70, respectively. In addition, the metal electrode layers 26 and 34 can be easily formed on the metal electrode layers 22 using a sputtering method or the like. Accordingly, it is possible to easily obtain a MIPS structure the AC operation of which has been improved.

Hereinafter, operational effects of the present embodiment will be described in detail. Whereas the workfunctions of the silicon electrode layers 62 and 70 are positioned at the band edges thereof, the workfunction of each metal electrode layer 22 is poisoned at an NMOSFET-side or PMOSFET-side band edge or near the mid-gap of the PMOSFET or the NMOSFET. Accordingly, contact resistance due to a difference in workfunction from the silicon electrodes arises in either the NMOSFET or the PMOSFET, or in both thereof.

Hence, in order to reduce contact resistance, the metal electrode layer 26 made of the metal M2N different in workfunction from the metal M1 is interposed between the metal electrode layer 22 and the n-type polysilicon electrode layer 62 and a film made of the metal M2P different in workfunction from the metal M1 is interposed between the metal electrode layer 22 and the p-type polysilicon electrode layer 70. The metals M2N and M2P are materials having workfunctions for alleviating band discontinuity between the metal electrode layer 22 and the silicon electrode layer 62 and between the metal electrode layer 22 and the silicon electrode layer 70, with respect to the majority carriers of the silicon electrode layers 62 and 70. Consequently, the contact resistance reduces and the AC operation of the semiconductor device improves.

In the present embodiment, the metal electrode layer 26 is interposed between the metal electrode layer 22 and the n-type polysilicon electrode layer 62. The metal electrode layers 22 and 26 are metals the workfunctions of which satisfy the above-described expression (1). Consequently, as illustrated in FIG. 16A, it is possible to alleviate band discontinuity between the metal electrode layer 22 and the metal electrode layer 26, with respect to electrons which are the majority carrier of the n-type polysilicon electrode layer 62. It is therefore possible to reduce contact resistance between the metal electrode layer 22 which is a metal gate electrode and the silicon electrode layer 62 which is a silicon gate electrode. AC operation can thus be improved.

In addition, the metal electrode layer 34 is interposed between the metal electrode layer 22 and the p-type polysilicon electrode layer 70. The metal electrode layers 22 and 34 are metals the workfunctions of which satisfy the above-described expression (2). Consequently, as illustrated in FIG. 16B, it is possible to alleviate band discontinuity between the metal electrode layer 22 and the silicon electrode layer 70, with respect to holes which are the majority carrier of the silicon electrode layer 70. It is therefore possible to reduce contact resistance between the metal electrode layer 22 which is a metal gate electrode and the silicon electrode layer 70 which is a silicon gate electrode. AC operation can thus be improved also in the PMOSFET.

The NMOSFET and the PMOSFET of the present embodiment include the metal electrode layers 26 and 34 underneath the n-type polysilicon electrode layer and the p-type polysilicon electrode layer, respectively. In addition, both the NMOSFET and the PMOSFET include the metal electrode layer 22 between the metal electrode layer 26 and the gate insulating film 25 and between the metal electrode layer 34 and the gate insulating film 27. On the other hand, an SRAM including the NMOSFET and the PMOSFET has a portion in which the gates of an NMOS and a PMOS are continuous. If metal electrode layers are formed using dissimilar metals for gate insulating films, so as to suit to both p- and n-type polysilicon electrode layers, then boundaries mix with each other in the portion in which the gates of the NMOS and the PMOS are continuous. This causes a threshold voltage (Vth) to vary widely. In contrast, in the present embodiment, both the NMOSFET and the PMOSFET have the metal electrode layers 22 of the same type. Thus, the abovementioned variation can be suppressed. This is particularly effective in controlling “Ion” in cases where the SRAM includes a pull-down gate (PD) having a wide diffusion layer and a path gate (PG) having a diffusion layer narrower than that of the PD, and the PD resides closer to the PMOSFET than the PG.

### Second Embodiment

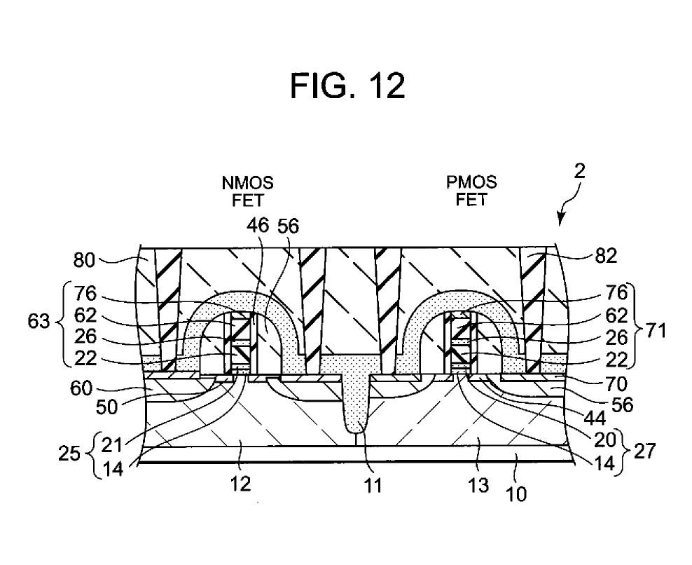

FIG. 12 is a cross-sectional view illustrating a semiconductor device 2 in accordance with a second embodiment. The semiconductor device 2 differs from the semiconductor device 1 of the first embodiment in that for both an NMOSFET and a PMOSFET, a silicon electrode layer 62 and a metal electrode layer 26 are respectively made of the same materials. Specifically, for both the NMOSFET and the PMOSFET, the silicon electrode layer 62 is made of n-type polysilicon. The metal electrode layer 22 is made of a metal M1 and the metal electrode layer 26 is made of a metal M2N. The metal M1 and the metal M2N satisfy the expression (1) mentioned in the first embodiment. The rest of the second embodiment is the same as the first embodiment.

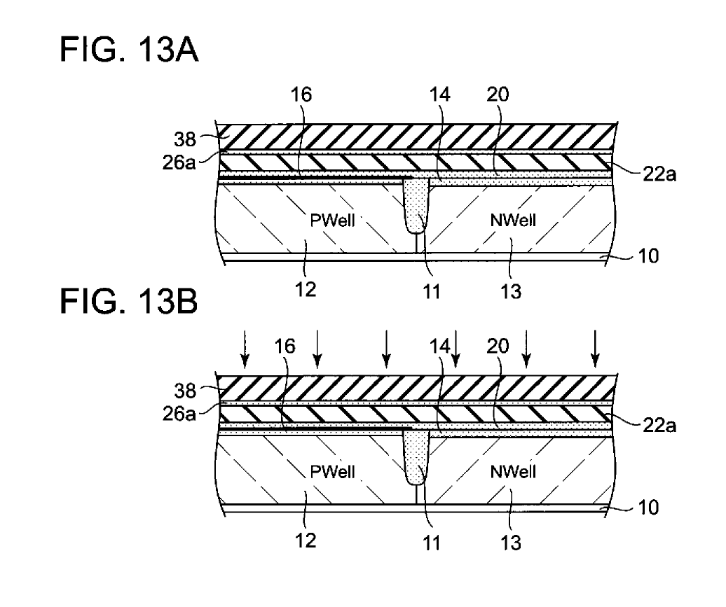

Next, a method for manufacturing a semiconductor device in accordance with an embodiment of the present invention will be described with reference to the cross-sectional views of FIG. 13. Note that manufacturing steps the same as those in the first embodiment will not be explained again.

The semiconductor device is fabricated in the same way as in the first embodiment for steps illustrated in FIGS. 2A to 3C. Next, as illustrated in FIG. 13A, a second metal layer 26a and a silicon layer 38 are formed in an NMOSFET-forming region and a PMOSFET-forming region. Both film-forming methods and film thicknesses are the same as those in the first embodiment.

Subsequently, as illustrated in FIG. 13B, an n-type dopant for the NMOSFET is implanted into the silicon layer 38. Implantation conditions are as follows:

Ge: implantation energy=30 keV, dose amount=5E14 atoms/cm², implantation angle=0°; and

P: implantation energy=5 keV, dose amount 5E15=atoms/cm², implantation angle=0°.

The implantation energy of P is preferably 2 keV or higher but not higher than 10 keV, and more preferably 4 keV or higher but not higher than 6 keV. The dose amount of P is preferably 1E15 atoms/cm² or larger but not larger than 5E15 atoms/cm², and more preferably 2E15 atoms/cm² or larger but not larger than 3E15 atoms/cm².

After that, manufacturing steps the same as those illustrated in FIG. 8A and subsequent figures in the first embodiment are used to obtain the semiconductor device 2 illustrated in FIG. 12.

The semiconductor device 2 of the present embodiment has the same advantageous effects as the semiconductor device 1. In addition, the number of steps required to manufacture the semiconductor device 2 in the present embodiment is fewer than that required in the manufacturing method of the first embodiment. Manufacturing costs can thus be reduced.

### Third Embodiment

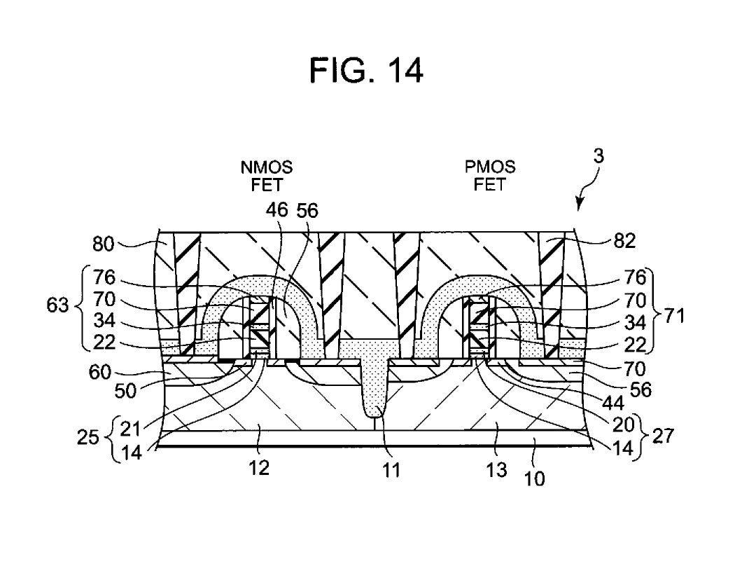

FIG. 14 is a cross-sectional view illustrating a semiconductor device 3 in accordance with a third embodiment. The semiconductor device 3 differs from the semiconductor device 1 of the first embodiment in that for both an NMOSFET and a PMOSFET, a silicon electrode layer 70 and a metal electrode layer 34 are respectively made of the same materials. Specifically, for both the NMOSFET and the PMOSFET, the silicon electrode layer 70 is made of p-type polysilicon. The metal electrode layer 22 is made of a metal M1 and the metal electrode layer 34 is made of a metal M2P. The metal M1 and the metal M2P satisfy the expression (2) mentioned in the first embodiment. The rest of the third embodiment is the same as the first embodiment.

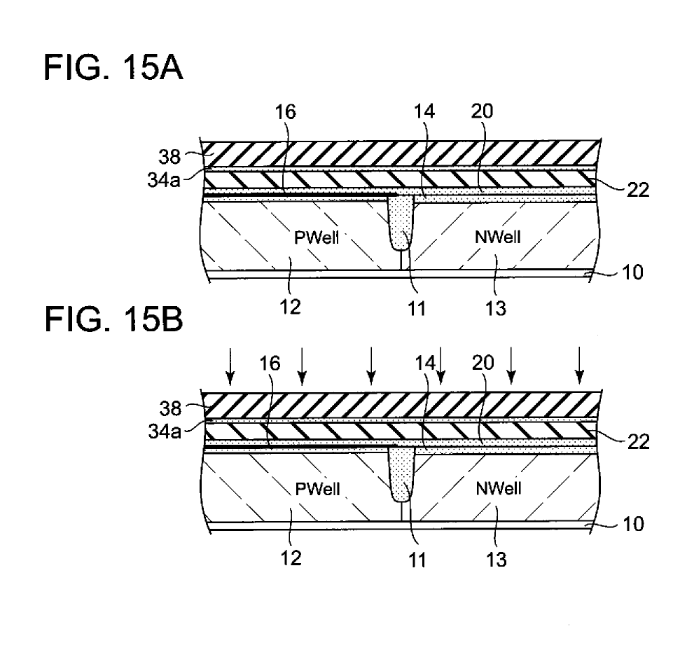

Next, a method for manufacturing a semiconductor device in accordance with an embodiment of the present invention will be described with reference to the cross-sectional views of FIG. 15. Note that manufacturing steps the same as those in the first embodiment will not be explained again.

The semiconductor device is fabricated in the same way as in the first embodiment for steps illustrated in FIGS. 2A to 3C. Next, as illustrated in FIG. 15A, a second metal layer 34a and a silicon layer 38 are formed in an NMOSFET-forming region and a PMOSFET-forming region. Both film-forming methods and film thicknesses are the same as those in the first embodiment.

Subsequently, as illustrated in FIG. 15B, a p-type dopant for the PMOSFET is implanted into the silicon layer 38. Implantation conditions are as follows:

Ge: implantation energy=30 keV, dose amount=5E14 atoms/cm², implantation angle=0°; and

B: implantation energy=1 keV, dose amount 5E15=atoms/cm², implantation angle=0°.

The implantation energy of B is preferably 0.5 keV or higher but not higher than 3 keV, and more preferably 1 keV or higher but not higher than 2 keV. The dose amount of B is preferably 1E15 atoms/cm² or larger but not larger than 5E15 atoms/cm², and more preferably 3E15 atoms/cm² or larger but not larger than 5E15 atoms/cm².

The semiconductor device 3 of the present embodiment has the same advantageous effects as the semiconductor device 1. In addition, as with the semiconductor device 2, the number of steps required to manufacture the semiconductor device 3 in the present embodiment is fewer than that required in the manufacturing method of the first embodiment. Manufacturing costs can thus be reduced.

While the embodiments of the present invention have been described with reference to the accompanying drawings, these embodiments are only illustrative of the present invention, and it is to be understood that various constitutions other than those described above may be adopted.

What is claimed is:

1. A semiconductor device comprising:
a semiconductor substrate;
an NMOS including a first gate insulating film on the substrate and a first gate electrode including a layer of a first metal on the first gate insulating film, a layer of a second metal on the layer of the first metal, and a layer of n-type doped polysilicon on the layer of the second metal; and
a PMOS including a second gate insulating film on the substrate and a second gate electrode including a layer of a third metal on the second gate insulating film, a layer of a fourth metal on the layer of the third metal, and a layer of p-type doped polysilicon on the layer of the fourth metal,
wherein EF1 which is a workfunction of the first metal, EF2 which is a workfunction of the second metal, EF3 which is a workfunction of the third metal, EF4 which is a workfunction of the fourth metal, EfN which is a Fermi level of the n-type doped polysilicon, and EfP which is a Fermi level of the p-type doped polysilicon satisfy the following expressions (1) and (2):

|EF1−EfN|>EF2−EfN; and (1)

|EF3−EfP|>EfP−EF4. (2)

2. The semiconductor device according to claim 1, wherein the first metal and the third metal are made of the same metal.

3. The semiconductor device according to claim 1, wherein the first metal has a workfunction of 4.2 to 4.9 eV and the second metal has a workfunction of 3.0 to 4.3 eV.

4. The semiconductor device according to claim 1, wherein the first metal is at least one metal selected from the group consisting of TiN, W, TaN, TaSiN, Ru and TiAlN and the second metal is at least one metal selected from the group consisting of Tb, Y, Nd, La, Sc, Lu, Mg, Ti, Hf, Al, Mn, Zr, Bi, Pb, Ta, Ag, V, Zn, Ti and Nb.

5. The semiconductor device according to claim 1, wherein the third metal has a workfunction of 4.2 to 4.9 eV and the fourth metal has a workfunction of 5.0 to 6.0 eV.

6. The semiconductor device according to claim 1, wherein the first metal is at least one metal selected from the group consisting of TiN, W, TaN, TaSiN, Ru and TiAlN and the fourth metal is at least one metal selected from the group consisting of Te, Re, Rh, Be, Co, Au, Pb, Ni, Ir and Pt.

7. The semiconductor device according to claim 1, wherein the first and second gate insulating films include at least one material selected from the group consisting of HfO₂, ZrO₂, HfSiON, La₂O₃ and HfAlO.
